(19) United States
(12) Patent Application Publication
(10) Pub. No.: US 2009/0058473 A1
(43) Pub. Date: Mar. 5, 2009

(54) ACTIVE PRE-EMPHASIS FOR PASSIVE RC NETWORKS

(75) Inventor: Bradford L. Hunter, South Burlington, VT (US)

Correspondence Address: HOFFMAN WARNICK LLC, 75 STATE ST, 14TH FLOOR, ALBANY, NY, 12207, US

(73) Assignee: International Business Machines Corporation, Armonk, NY (US)

(21) Appl. No.: 11/850,347

(22) Filed: Sep. 5, 2007

(51) Int. Cl. G11C 27/02; G06F 17/50; H04B 1/10

(52) U.S. Cl. 327/95; 327/552; 716/12

(57) ABSTRACT

An approach that provides active pre-emphasis for a passive RC network is described. In one embodiment, there is a circuit that comprises an RC filter including a resistive divider formed from a first resistor and a second resistor and a filtering capacitor. The first resistor is configured to receive an input voltage and the second resistor and filtering capacitor are in parallel and configured to generate a reference voltage that is a percentage of the input voltage. An operational amplifier is coupled to the RC filter. A first multiplexer controlled by a pulse pre-emphasis signal is coupled to the operational amplifier and the RC filter. A second multiplexer controlled by a sample and hold clocking signal has inputs that are coupled to the first multiplexer and ground.

### BACKGROUND

This disclosure relates generally to resistor and capacitor (RC) networks used to perform passive filtering and voltage division, and more specifically to a circuit and circuit design structure that encompasses an RC network with pulsed pre-emphasis.

An RC network that performs passive filtering and voltage division has utility with a data converter. In such a scenario where an RC network is used to perform passive filtering and voltage division for a data converter, output from the RC network is often sampled by driving a voltage onto a sampling capacitor. The sampling capacitor usually contains an initial charge from a previous sample and that can result in a disturbance in driving a desired voltage onto the sampling capacitor. The bandwidth of the RC network sets the speed at which the sampling capacitor voltage can resolve the disturbance and settle to the desired voltage value. In most data conversion applications there is a desire to set the bandwidth of the RC network to a bandwidth that is as low as possible in order to attain greater noise rejection. Reducing the bandwidth of the RC network too much will impair its ability to quickly resolve any disturbances that occur while driving the desired voltage onto the sampling capacitor. This leads to sampling errors in the data conversion.

### SUMMARY

In one embodiment, there is a circuit that comprises an RC filter including a resistive divider formed from a first resistor and a second resistor and a filtering capacitor. The first resistor is configured to receive an input voltage and the second resistor and filtering capacitor are in parallel and configured to generate a reference voltage that is a percentage of the input voltage. An operational amplifier is coupled to the RC filter. A first multiplexer is controlled by a pulse pre-emphasis signal and coupled to the operational amplifier and the RC filter. A second multiplexer controlled by a sample and hold clocking signal has inputs that are coupled to the first multiplexer and ground.

In a second embodiment, there is a method of driving a voltage during a sample and hold operation performed for data conversion. The method in this embodiment comprises dividing an input voltage to a reference voltage that is a percentage of the input voltage; filtering the reference voltage to a predetermined cut-off frequency; driving the reference voltage to a sampling element as a clocking signal transitions from a sample operation to a hold operation; applying a pulse pre-emphasis signal around the transition from the sample operation to the hold operation for a predetermined time interval; actively driving the sampling element with a buffered version of the reference voltage during the predetermined time interval that the pulse pre-emphasis signal is applied to remove any chance for a disturbance; and maintaining the sampling element at the reference voltage during the remainder of the hold operation, after the predetermined time interval has ended and the pulse pre-emphasis signal has been turned off.

In a third embodiment, there is a design structure embodied in a machine readable medium used in a design process of a circuit. The design structure comprises an RC filter including a resistive divider formed from a first resistor and a second resistor and a filtering capacitor. The first resistor is configured to receive an input voltage and the second resistor and filtering capacitor are in parallel and configured to generate a reference voltage that is a percentage of the input voltage. An operational amplifier is coupled to the RC filter. A first multiplexer controlled by a pulse pre-emphasis signal is coupled to the operational amplifier and the RC filter. A second multiplexer controlled by a sample and hold clocking signal has inputs of the second multiplexer that are coupled to the first multiplexer and ground.

### BRIEF DESCRIPTION OF THE DRAWINGS

FIG. 1 shows an RC filter circuit with pulse pre-emphasis according to one embodiment of this disclosure;

FIG. 2 shows a timing diagram for the circuit shown in FIG. 1;

FIG. 3 shows a simulation of the behavior of the circuit shown in FIG. 1;

FIG. 4 shows a block diagram of a general-purpose computer system which can be used to implement the circuit and circuit design structure shown in FIG. 1; and

FIG. 5 shows a flow diagram describing a design process that can be used in the semiconductor design, manufacturing and/or test of the circuit shown in FIG. 1.

### DETAILED DESCRIPTION

Embodiments of this disclosure are directed to a circuit and circuit design structure that can artificially increase the bandwidth of an RC network used to perform the function of passive filtering and voltage division during instances when a voltage disturbance occurs and then lower the artificially increased bandwidth to its normal operating bandwidth after the disturbance has been settled. Artificially increasing the bandwidth of the RC network for a short duration enables the circuit and circuit design structure to quickly settle any voltage disturbances while maintaining high noise rejection.

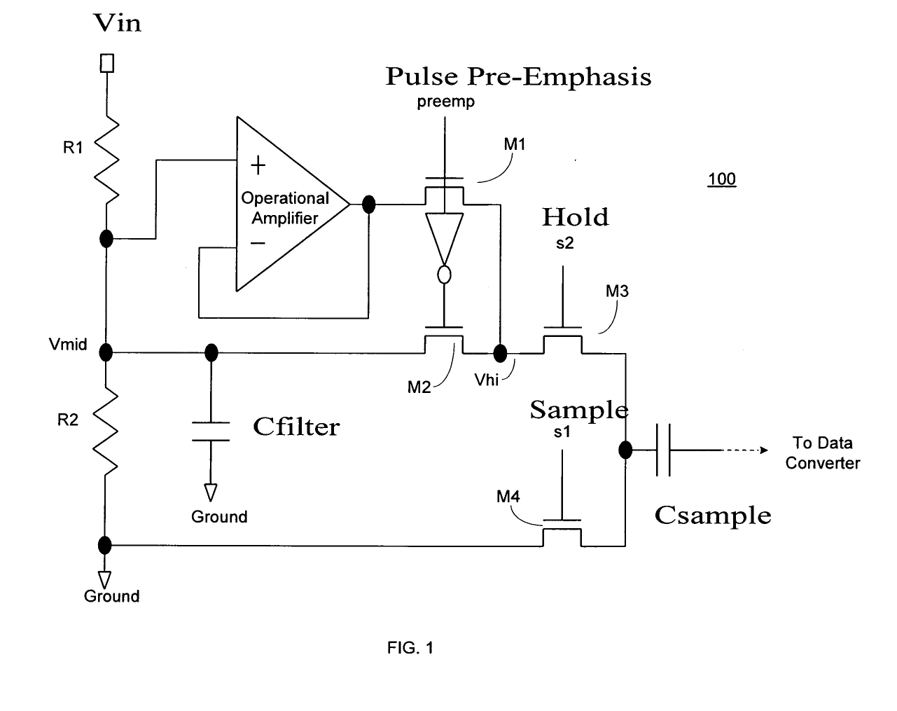

FIG. 1 shows an RC filter circuit 100 with pulse pre-emphasis according to one embodiment of this disclosure. Although the description that follows is directed to applying the circuit 100 to data conversion, those skilled in the art will recognize that this circuit is suitable for use in areas where resistor ladders and resistor dividers are employed or wherever it is necessary to divide a voltage down.

The circuit 100 of FIG. 1 comprises an RC filter that includes a voltage divider formed from resistors R1 and R2 and filtering capacitor Cfilter. Resistor R1 receives an input voltage Vin and resistor R2 and filtering capacitor Cfilter, which are in parallel to each other, generate a reference voltage Vmid at one net formed therebetween that is a percentage of the input voltage Vin.

The circuit 100 further includes an operational amplifier coupled to the RC filter. In one embodiment as shown in FIG. 1, the operational amplifier is connected in a unity gain amplifier configuration that acts as a voltage buffer (i.e., the output voltage is set to equal the input voltage). In this embodiment, the operational amplifier gain should be as high as possible to reduce the output offset and gain errors. Therefore, a non-inverting input (i.e., the + terminal) of the operational amplifier is coupled to a net formed between resistor R1, resistor R2 and filtering capacitor Cfilter and the inverting input (i.e., the − terminal) of the amplifier is connected to the output of the operational amplifier. Connecting the output of the amplifier to the inverting input terminal creates an input to output unity gain transfer function. With this configuration, the operational amplifier receives reference voltage Vmid as an input at the non-inverting terminal and generates a buffered version of Vmid as an output.

As shown in FIG. 1, the circuit includes two multiplexers, wherein one multiplexer is formed from switches M1 and M2, while a second multiplexer is formed from switches M3 and M4. Although the multiplexers of FIG. 1 are shown as metal oxide semiconductor (MOS) technology (i.e., field effect transistor switches), those skilled in the art will recognize that the multiplexers can be implemented with any type of ideal switch.

In circuit 100, switches M1 and M2 are controlled by a pulse pre-emphasis signal that is generated by a pulse pre-emphasis generating circuit (not shown in FIG. 1) such as a clock generation circuit. The pulse pre-emphasis signal is a narrow pulse that, as will be explained below, provides the RC filter an active emphasis for a short period of time. Because the control lines of a 2 to 1 multiplexer must be complementary, the pulse pre-emphasis signal supplied to the gates of M1 and M2 are complements. In FIG. 1, an inverter inverts the pulse pre-emphasis signal supplied to the gate of M2. The drain of switch M1 receives the buffered version of Vmid, generated from the operational amplifier and the source of switch M1 is coupled to a net (Vhi) formed between switches M1, M2 and M3. The drain of switch M2 receives the reference voltage Vmid, while its source is coupled to the net (Vhi) formed between switches M1, M2 and M3.

Switches M3 and M4 are controlled by a sample and hold clocking signal that is generated by a sample and hold generating circuit (not shown in FIG. 1) such as a clock generation circuit. The sample and hold clocking signals are used to interface signals to a data converter. In the embodiment of FIG. 1, the Vmid signal is analog and the sample and hold clocking signals are applied to an analog to digital converter (A/D converter). In essence, the sample and hold clocking signals serve to hold the sampled value of Vmid steady while the A/D converter or other components perform a conversion operation.

As shown in FIG. 1, the drain of switch M3 is coupled to the net (Vhi) formed between switches M1, M2 and M3 and the source of M3 supplies the input to a sampling capacitor Csample. In this embodiment, the data converter samples the voltage off the sampling capacitor Csample. Those skilled in the art will recognize that the data converter does not necessarily have to sample the voltage off a sampling capacitor but instead may use other components such as a comparator. Referring back to FIG. 1, the drain of switch M4 is connected to ground, while its source supplies an input to the sampling capacitor Csample.

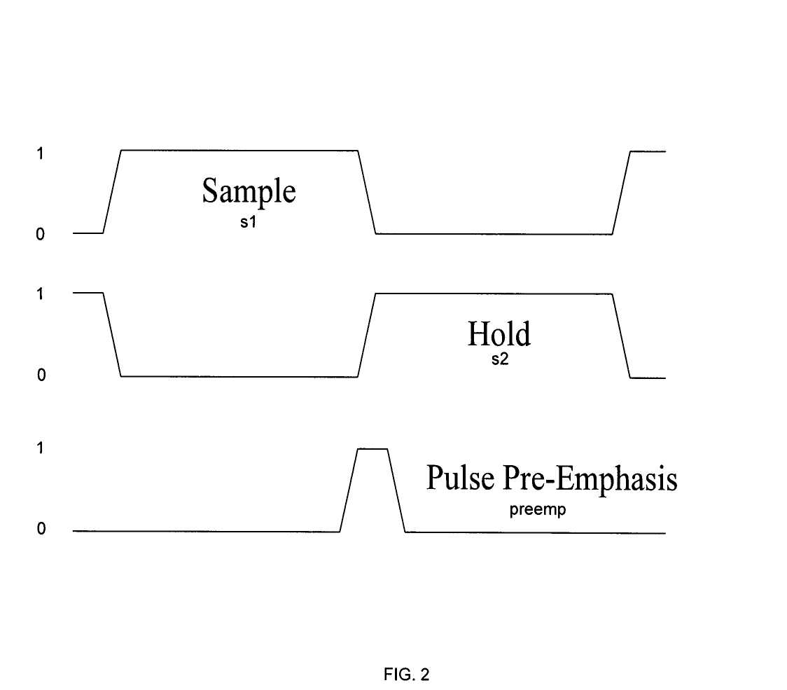

FIG. 2 shows a timing diagram that explains the timing of the sample and hold clocking signal as well as the pulse pre-emphasis signal. In particular, the timing diagram shows a timing relationship of voltage versus time with respect to the sample, hold and pulse pre-emphasis signals. As indicated in FIG. 2, when the sample signal is high (i.e., 1) the hold signal is always low (i.e., 0). Because the sample and hold signals are always inverses of each other, when the sample signal is low the hold signal is high. As shown in FIG. 2, the pulse pre-emphasis signal occurs just before or around the beginning of the hold phase and lasts for only a short time interval with respect to the duration that the hold signal is high.

Applying the timing diagram of FIG. 2 to circuit 100 provides an understanding on how sample and hold operations are performed with a data converter. Initially, a sample operation is performed to set up the circuit 100. During this initial sample operation, the sample signal is high and the hold signal is low. This opens switch M3 and closes switch M4, which in turn sets the sampling capacitor Csample to ground.

Before the sample signal transitions to low and the hold signal transitions to high, the pulse pre-emphasis signal is applied to switches M1 and M2 for a short time interval. In this interval that the pulse-pre emphasis signal is high (i.e., the signal is applied to switches M1 and M2), switch M1 is closed while switch M2 is open. And because the circuit 100 is transitioning from a sample phase to a hold phase (i.e., hold becomes high and sample becomes low), switch M3 closes and switch M4 opens, changing the input supplied to the sampling capacitor from ground to the buffered version of the reference voltage Vmid. During the interval that the pulse pre-emphasis signal is high, the operational amplifier is used to ensure that the buffered version of the reference voltage Vmid is supplied to the input of the sampling capacitor Csample. When the end of the pulse pre-emphasis time interval is reached, the pulse pre-emphasis signal turns low, opening switch M1 and closing switch M2. This results in the RC filter supplying the reference voltage Vmid to the sampling capacitor Csample via switches M2 and M3.

The operational amplifier, switches M1 and M2, inverter and pulse pre-emphasis signal ensure that circuit 100 is able to quickly resolve voltage disturbances that arise as the voltage supplied to the input of the sampling capacitor Csample transitions from ground to Vmid, while simultaneously maintaining high noise rejection. Considering circuit 100 without the operational amplifier, switches M1 and M2, inverter and pulse pre-emphasis signal provides an understanding on how voltage disturbances are quickly resolved without negating noise rejection.

In this scenario where circuit 100 does not include the operational amplifier, switches M1 and M2, inverter and pulse pre-emphasis signal, a charge sharing event will occur as there is a transition from the sample operation to a hold operation. As mentioned above, during this transition from sample operation to a hold operation, hold becomes high and sample becomes low, closing switch M3 and opening switch M4. The sampling capacitor Csample consequently transitions from ground to the reference voltage Vmid. A charge sharing event occurs because the capacitor filter Cfilter is holding the voltage at the reference voltage Vmid and the sampling capacitor Csample is initialized to ground. This charge sharing event causes a disturbance that is a temporary voltage change on the reference voltage Vmid. This disturbance represents an error in the voltage reference Vmid and if Vmid does not settle to its expected voltage by the end of the hold phase then the data converter is not going to sample the correct voltage.

The use of the operational amplifier, switches M1 and M2, inverter and pulse pre-emphasis signal in circuit 100 enables the circuit to quickly resolve disturbances by actively driving the desired voltage onto the sampling capacitor while maintaining a high noise rejection of the RC filter. In particular, during the window that a charge sharing event occurs between the filtering capacitor Cfilter and the sampling capacitor Csample, the pulse pre-emphasis signal goes high closing switch M1 and opening switch M2. During this window the operational amplifier provides the buffered version of the voltage reference Vmid to the sampling capacitor Csample via switches M1 and M3. Because switch M2 is open, capacitor filter Cfilter is disconnected from sampling capacitor Csample, obviating a charge sharing event. Since the operational amplifier is a voltage buffer it can drive the buffered version of the reference voltage Vmid to the sampling capacitor Csample very rapidly. This ensures that the operational amplifier is only engaged during the short time interval that the pulse pre-emphasis signal is high in the hold operation. Otherwise, the operational amplifier is disconnected and the RC filter supplies the voltage reference Vmid to the sampling capacitor via switches M2 and M3. Disconnecting the operational amplifier is necessary because the amplifier can have a DC offset error and DC gain error that would cause a sampling error.

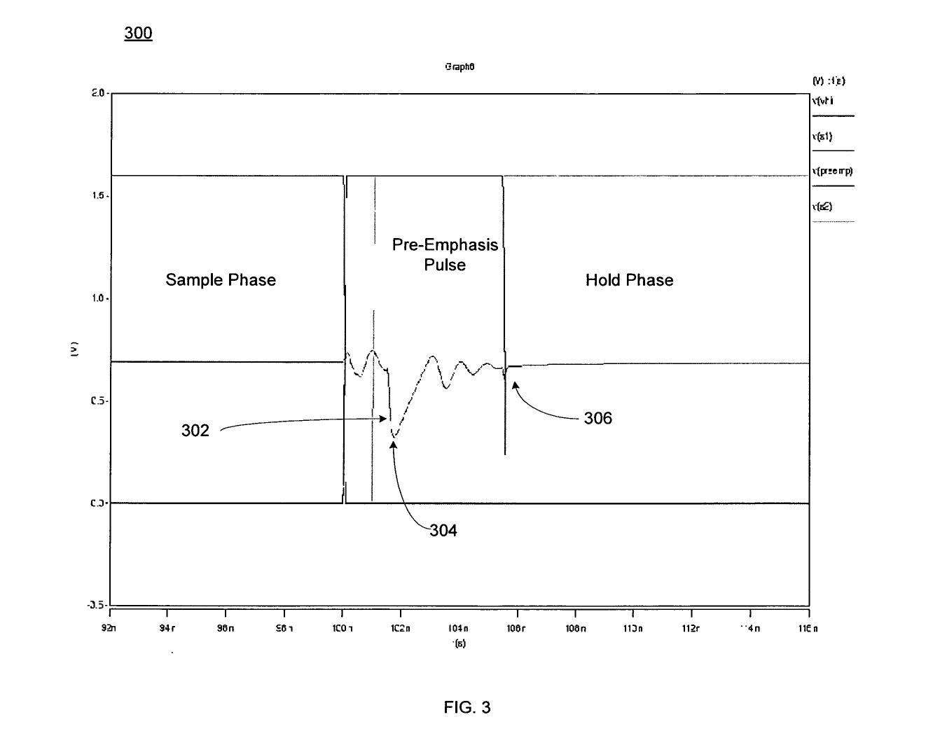

With this configuration there is still some charge sharing but it is much smaller as compared to a circuit that does not utilize the operational amplifier, switches M1 and M2, inverter and pulse pre-emphasis signal. FIG. 3 shows a simulation 300 of the behavior of the circuit 100 that demonstrate its results. In particular, the simulation 300 shows the signals of FIG. 2 stacked on top of each other. Moreover, the simulation 300 shows the behavior of the signal during the time interval that the pulse pre-emphasis is applied. Reference number 302 in FIG. 3 represents the net (Vhi) formed between switches M1, M2 and M3. Reference number 304 represents the charge sharing event and where the operational amplifier begins to drive the sampling capacitor Csample to the buffered version of the reference voltage Vmid. Reference number 306 shows where the RC filter obtains control in the hold phase and settles the operational amplifier offset. From the results shown in the simulation 300, it is apparent that circuit 100 does not sacrifice bandwidth while simultaneously maintaining high noise rejection.

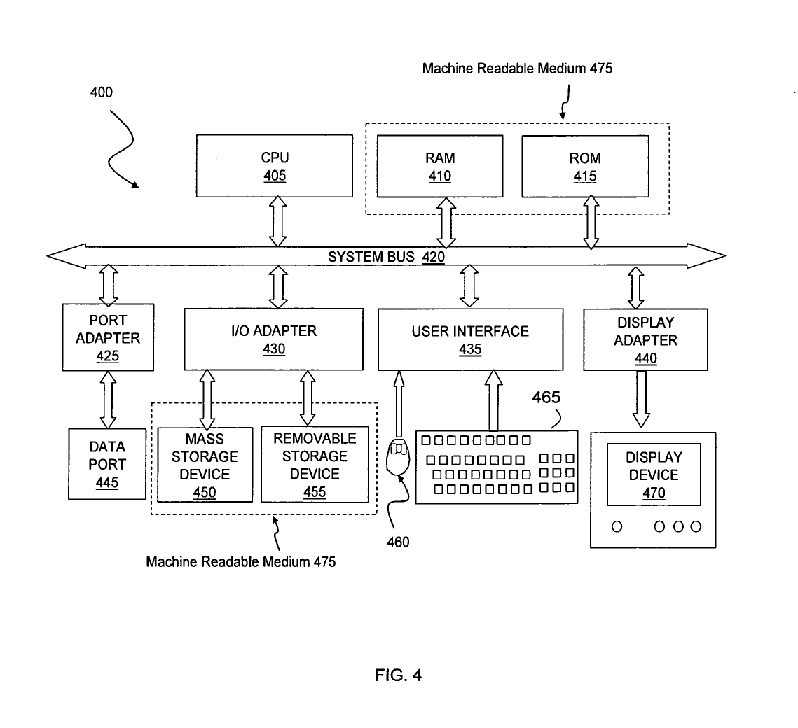

FIG. 4 illustrates a block diagram of a general-purpose computer system which can be used to implement the circuit and circuit design structure described herein. The design structure may be coded as a set of instructions on removable or hard media for use by general-purpose computer. FIG. 4 is a schematic block diagram of a general-purpose computer for practicing the present invention. FIG. 4 shows a computer system 400, which has at least one microprocessor or central processing unit (CPU) 405. CPU 405 is interconnected via a system bus 420 to machine readable media 475, which includes, for example, a random access memory (RAM) 410, a read-only memory (ROM) 415, a removable and/or program storage device 455 and a mass data and/or program storage device 450. An input/output (I/O) adapter 430 connects mass storage device 450 and removable storage device 455 to system bus 420. A user interface 435 connects a keyboard 465 and a mouse 460 to system bus 420, and a port adapter 425 connects a data port 445 to system bus 420 and a display adapter 440 connects a display device 470. ROM 415 contains the basic operating system for computer system 400. Examples of removable data and/or program storage device 455 include magnetic media such as floppy drives, tape drives, portable flash drives, zip drives, and optical media such as CD ROM or DVD drives. Examples of mass data and/or program storage device 450 include hard disk drives and non-volatile memory such as flash memory. In addition to keyboard 465 and mouse 460, other user input devices such as trackballs, writing tablets, pressure pads, microphones, light pens and position-sensing screen displays may be connected to user interface 435. Examples of display device 470 include cathode-ray tubes (CRT) and liquid crystal displays (LCD).

A machine readable computer program may be created by one of skill in the art and stored in computer system 400 or a data and/or any one or more of machine readable medium 475 to simplify the practicing of this invention. In operation, information for the computer program created to run the present invention is loaded on the appropriate removable data and/or program storage device 455, fed through data port 445 or entered using keyboard 465. A user controls the program by manipulating functions performed by the computer program and providing other data inputs via any of the above mentioned data input means. Display device 470 provides a means for the user to accurately control the computer program and perform the desired tasks described herein.

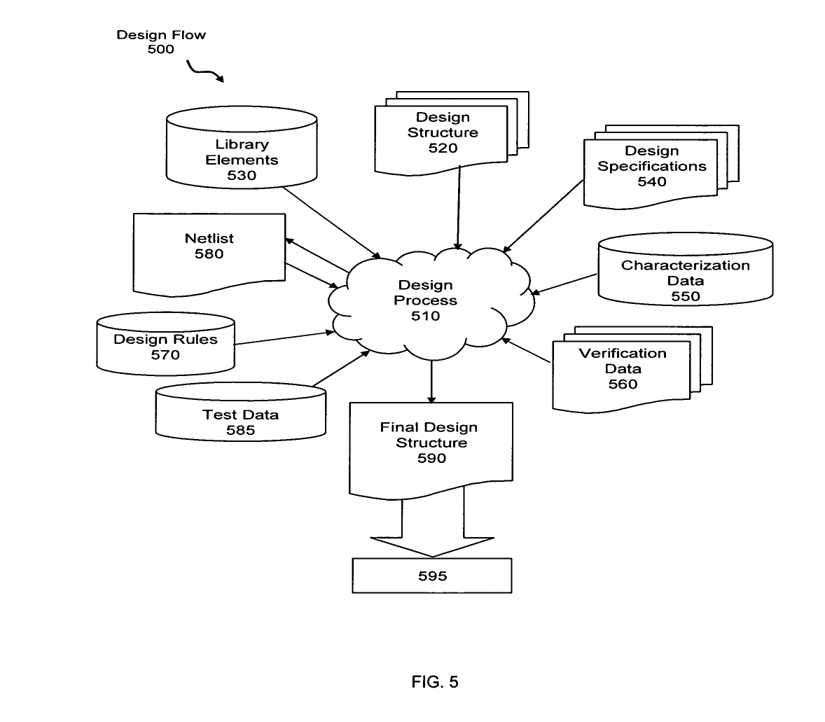

FIG. 5 shows a block diagram of an example design flow 500. Design flow 500 may vary depending on the type of IC being designed. For example, a design flow 500 for building an application specific IC (ASIC) will differ from a design flow 500 for designing a standard component. Design structure 520 is an input to a design process 510 and may come from an IP provider, a core developer, or other design company. Design structure 520 comprises the circuit 100 shown in FIG. 1 in the form of schematics or HDL, a hardware-description language, (e.g., Verilog, VHDL, C, etc.). Design structure 520 may be on one or more of machine readable medium 475 as shown in FIG. 4. For example, design structure 520 may be a text file or a graphical representation of the circuit 100. Design process 510 synthesizes (or translates) the circuit 100 into a netlist 580, where netlist 580 is, for example, a list of wires, transistors, logic gates, control circuits, I/O, models, etc. and describes the connections to other elements and circuits in an integrated circuit design and recorded on at least one of machine readable medium 475.

Design process 510 includes using a variety of inputs; for example, inputs from library elements 530 which may house a set of commonly used elements, circuits, and devices, including models, layouts, and symbolic representations, for a given manufacturing technology (e.g. different technology nodes, 32 nm, 45 nm, 90 nm, etc.), design specifications 540, characterization data 550, verification data 560, design rules 570, and test data files 585, which may include test patterns and other testing information. Design process 510 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 510 without deviating from the scope and spirit of the invention.

Ultimately design process 510 translates the circuit 100, along with the rest of the integrated circuit design (if applicable), into a final design structure 590 (e.g., information stored in a GDS storage medium). Final design structure 590 may comprise information such as, for example, test data files, design content files, manufacturing data, layout parameters, wires, levels of metal, vias, shapes, test data, data for routing through the manufacturing line, and any other data required by a semiconductor manufacturer to produce the circuit 100. Final design structure 590 may then proceed to a stage 595 of design flow 500, where stage 595 is, for example, where final design structure 590 proceeds to tape-out, i.e., is released to manufacturing, is sent to another design house or is sent back to the customer.

It is apparent that there has been provided with this disclosure a circuit and circuit design structure that encompasses an RC network with pulse pre-emphasis. While the disclosure has been particularly shown and described in conjunction with a preferred embodiment thereof, it will be appreciated that variations and modifications will occur to those skilled in the art. Therefore, it is to be understood that the appended claims are intended to cover all such modifications and changes as fall within the true spirit of the invention.

What is claimed is:

1. A circuit, comprising:
an RC filter including a resistive divider formed from a first resistor and a second resistor and a filtering capacitor, wherein the first resistor is configured to receive an input voltage and the second resistor and filtering capacitor are in parallel and configured to generate a reference voltage that is a percentage of the input voltage;
an operational amplifier coupled to the RC filter;
a first multiplexer controlled by a pulse pre-emphasis signal, wherein the first multiplexer is coupled to the operational amplifier and the RC filter; and
a second multiplexer controlled by a sample and hold clocking signal, wherein inputs of the second multiplexer are coupled to the first multiplexer and ground.

2. The circuit according to claim 1, wherein a non-inverting input of the operational amplifier is coupled to a net formed between the first resistor, second resistor and filtering capacitor and an output of the operational amplifier is connected to an inverting input of the operational amplifier.

3. The circuit according to claim 2, wherein inputs of the first multiplexer are coupled to the output of the operational amplifier and the net formed between the first resistor, second resistor and filtering capacitor in the RC filter.

4. The circuit according to claim 1, further comprising a sampling capacitor coupled to the second multiplexer, wherein the sampling capacitor is connected to ground during a sample phase and supplied with the reference voltage during a hold phase.

5. The circuit according to claim 4, further comprising a data converter coupled to an output of the sampling capacitor.

6. A method of driving a voltage during a sample and hold operation performed for data conversion, comprising:
dividing an input voltage to a reference voltage that is a percentage of the input voltage;
filtering the reference voltage to a predetermined cut-off frequency;
driving the reference voltage to a sampling element as a clocking signal transitions from a sample operation to a hold operation;
applying a pulse pre-emphasis signal around the transition from the sample operation to the hold operation for a predetermined time interval;
actively driving the sampling element with a buffered version of the reference voltage during the predetermined time interval that the pulse pre-emphasis signal is applied to remove any chance for a disturbance; and
maintaining the sampling element at the reference voltage during the remainder of the hold operation after the predetermined time interval has ended and the pulse pre-emphasis signal has been turned off.

7. The method according to claim 6, wherein the predetermined time interval for applying the pulse pre-emphasis signal is less than the duration of the hold operation.

8. The method according to claim 6, further comprising sampling the sampling element for data conversion.

9. The method according to claim 6, further comprising driving the sampling element to ground as the clocking signal transitions from a hold operation to a sample operation.

10. A design structure embodied in a machine readable medium used in a design process of a circuit, the design structure comprising:
an RC filter including a resistive divider formed from a first resistor and a second resistor and a filtering capacitor, wherein the first resistor is configured to receive an input voltage and the second resistor and filtering capacitor are in parallel and configured to generate a reference voltage that is a percentage of the input voltage;
an operational amplifier coupled to the RC filter;
a first multiplexer controlled by a pulse pre-emphasis signal, wherein the first multiplexer is coupled to the operational amplifier and the RC filter; and
a second multiplexer controlled by a sample and hold clocking signal, wherein inputs of the second multiplexer are coupled to the first multiplexer and ground.

11. The design structure of claim 10, wherein a final design structure comprises a netlist which describes the circuit.

12. The design structure of claim 10, wherein a final design structure resides on a GDS storage medium.

13. The design structure of claim 10, wherein a final design structure includes test data files, characterization data, verification data or design specifications.
